(19) United States
(12) Patent Application Publication
(10) Pub. No.: US 2025/0176321 A1
(43) Pub. Date: May 29, 2025

(54) SEMICONDUCTOR LIGHT-EMITTING DEVICE, MANUFACTURING METHOD THEREOF, AND DISPLAY APPARATUS INCLUDING THE SAME

(71) Applicant: SAMSUNG ELECTRONICS CO., LTD., Suwon-si (KR)

(72) Inventors: Joohun HAN, Suwon-si (KR); Joosung KIM, Suwon-si (KR); Chanwook BAIK, Suwon-si (KR); Junhee CHOI, Suwon-si (KR); Narae HAN, Suwon-si (KR)

(73) Assignee: SAMSUNG ELECTRONICS CO., LTD., Suwon-si (KR)

(21) Appl. No.: 18/960,967

(22) Filed: Nov. 26, 2024

(30) Foreign Application Priority Data
Nov. 28, 2023 (KR) 10-2023-0168240

(51) Int. Cl. H01L 33/44; H01L 25/075; H01L 33/00; H01L 33/04

(52) U.S. Cl. CPC H10H 20/84; H01L 25/0753; H10H 20/01; H10H 20/811; H10H 20/034

(57) ABSTRACT

A semiconductor light-emitting device includes a light-emitting stack structure including a first semiconductor layer, an active layer provided on the first semiconductor layer, and a second semiconductor layer provided on the active layer, and a first passivation film provided on a side surface of the light-emitting stack structure.

### CROSS-REFERENCE TO RELATED APPLICATION

This application is based on and claims priority under 35 U.S.C. § 119 to Korean Patent Application No. 10-2023-0168240, filed on Nov. 28, 2023, in the Korean Intellectual Property Office, the disclosure of which is incorporated by reference herein in its entirety.

### BACKGROUND

### 1. Field

One or more example embodiments of the disclosure relate to a semiconductor light-emitting device with improved luminescence efficiency, a manufacturing method thereof, and a display apparatus including the semiconductor light-emitting device.

### 2. Description of the Related Art

Light-emitting diodes (LEDs) are known as a next-generation light source having advantages of a longer lifespan, lower power consumption, a faster response speed, improved environmental friendliness, etc. compared to other light sources of the related art, and due to such advantages, there has been a growing industrial demand for the LEDs. LEDs may be applied to various products such as a lighting apparatus, a backlight of a display apparatus, etc.

Recently, micro-or nano-sized subminiature LEDs using a Group II-VI or Group III-V compound semiconductor have been developed. In addition, micro LED displays to which such subminiature LEDs are directly applied as light-emitting elements of display pixels have been developed. However, the miniaturization of the LEDs to a micro or nano unit diminishes the luminescence efficiency of the LEDs.

### SUMMARY

One or more example embodiments provide a semiconductor light-emitting device with improved luminescence efficiency.

One or more example embodiments provide a method of manufacturing the semiconductor light-emitting device with improved luminescence efficiency.

One or more example embodiments provide a display apparatus including the semiconductor light-emitting device with improved luminescence efficiency.

Additional aspects will be set forth in part in the description which follows and, in part, will be apparent from the description, or may be learned by practice of the presented embodiments of the disclosure.

According to an aspect of an example embodiment of the disclosure, a semiconductor light-emitting device includes a light-emitting stack structure including a first semiconductor layer, an active layer provided on the first semiconductor layer, and a second semiconductor layer provided on the active layer, and a first passivation film provided on a side surface of the light-emitting stack structure, wherein the light-emitting stack structure is configured to emit light having an emission peak wavelength in a range of about 400 nm to about 550 nm, and the first passivation film includes a tantalum oxide (TaxOy), and a composition ratio of the tantalum oxide of the first passivation film has a range of 0.1≤y/x≤10.

A thickness of the first passivation film may be in a range of about 1 nm to about 50 nm.

The first passivation film may include Ta₂O₃ or Ta₂O₅.

A second passivation film may be further provided on the first passivation film.

The second passivation film may include at least one of SiO₂, SiN, SiCN, SiOC, SiON, SiOCN, HfOₓ, AlOₓ, ZrOₓ, AlN, AlOₓN_{y}, Ta₂O₃, or Ta₂O₅.

The second passivation film may be stacked in one to five layers.

The second passivation film may include an amorphous material.

A thickness of the second passivation film may be in a range of about 1 nm to about 15 nm.

The first semiconductor layer may include a core rod, a plurality of nanopores open in an outward direction from the core rod, and quantum dots dispersed in the plurality of nanopores.

The plurality of nanopores may be provided radially from the core rod in a transverse section of the first semiconductor layer.

A diameter of the core rod may be in a range of about ⅓ to about ⅕ of a diameter of the light-emitting stack structure.

The semiconductor light-emitting device may have a diameter in a range of about 0.5 μm to about 2 μm.

The semiconductor light-emitting device may have a height in a range of about 2 μm to about 7 μm.

According to an aspect of an example embodiment of the disclosure, a display apparatus includes a plurality of pixel electrodes, a common electrode corresponding to the plurality of pixel electrodes, a plurality of semiconductor light-emitting devices connected between each pixel electrode of the plurality of pixel electrodes and the common electrode, and a driver circuit layer configured to drive the plurality of semiconductor light-emitting devices, wherein each semiconductor light-emitting device of the plurality of semiconductor light-emitting devices includes a light-emitting stack structure including a first semiconductor layer, an active layer provided on the first semiconductor layer, and a second semiconductor layer provided on the active layer, and a first passivation film provided on a side surface of the light-emitting stack structure, and wherein the light-emitting stack structure is configured to emit light having an emission peak wavelength in a range of about 400 nm to about 550 nm, and the first passivation film includes a tantalum oxide (TaxOy), and a composition ratio of the tantalum oxide of the first passivation film has a range of 0.1≤y/x≤10.

According to an aspect of an example embodiment of the disclosure, a method of manufacturing a semiconductor light-emitting device includes forming a first semiconductor layer on a substrate, forming an active layer on the first semiconductor layer, forming a second semiconductor layer on the active layer, forming a plurality of light-emitting stack structures by etching the first semiconductor layer, the active layer, and the second semiconductor layer, and depositing a first passivation film on the plurality of light-emitting stack structures, wherein the plurality of light-emitting stack structures emit light having an emission peak wavelength in a range of about 400 nm to about 550 nm, the first passivation film includes a tantalum oxide (TaxOy), and a composition ratio of the tantalum oxide of the first passivation film has a range of 0.1≤y/x≤10.

A deposition temperature of the first passivation film may be 250° C. or less.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a schematic diagram of a semiconductor light-emitting device according to an example embodiment;

FIG. 2 is a plan view of the semiconductor light-emitting device of FIG. 1;

FIG. 3 is a diagram illustrating an example in which a semiconductor light-emitting device includes a second passivation film according to an example embodiment;

FIG. 4 is a diagram illustrating an example in which a semiconductor light-emitting device includes a superlattice layer and an electron blocking layer according to an example embodiment;

FIGS. 5A and 5B are diagrams each illustrating an example in which a semiconductor light-emitting device includes quantum dots according to example embodiments;

FIG. 6 is a diagram illustrating an example in which a first passivation film is provided on a portion of a side surface of a semiconductor light-emitting device according to an example embodiment;

FIG. 7 illustrate graphs showing a change in a photo luminescence (PL) intensity according to a wavelength in a semiconductor light-emitting device according to an example embodiment and a semiconductor light-emitting device according to a comparative example, respectively;

FIGS. 8A to 8E are diagrams each illustrating a method of manufacturing a semiconductor light-emitting device according to one or more example embodiments;

FIG. 9 is a flowchart illustrating a method of manufacturing a first passivation film of a semiconductor light-emitting device, according to an example embodiment;

FIG. 10 is a flowchart illustrating a method of manufacturing a first passivation film and a second passivation film of a semiconductor light-emitting device, according to an example embodiment;

FIG. 11 illustrate graphs showing a change in a PL intensity according to an emission wavelength with respect to a first passivation deposition temperature of a semiconductor light-emitting device according to example embodiments;

FIG. 12 illustrate graphs showing a change in a PL intensity according to an emission wavelength with respect to a first passivation deposition time in a semiconductor light-emitting device according to example embodiments and a semiconductor light-emitting device according to a comparative example, respectively;

FIG. 13 is a schematic diagram of a display apparatus according to an example embodiment;

FIG. 14 is a diagram of an array layer of a display apparatus according to an example embodiment;

FIG. 15 is a schematic block diagram of an electronic apparatus according to an example embodiment;

FIG. 16 is a diagram illustrating an example in which a display apparatus according to an example embodiment is applied to a mobile apparatus;

FIG. 17 is a diagram illustrating an example in which a display apparatus according to an example embodiment is applied to a display apparatus for vehicles;

FIG. 18 is a diagram illustrating an example in which a display apparatus according to an example embodiment is applied to augmented reality glasses or virtual reality glasses;

FIG. 19 is a diagram illustrating an example in which a display apparatus according to an example embodiment is applied to a signage; and

FIG. 20 is a diagram illustrating an example in which a display apparatus according to an example embodiment is applied to a wearable display.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the drawings, a semiconductor light-emitting device, a method of manufacturing the semiconductor light-emitting device, and a display apparatus including the semiconductor light-emitting device according to various embodiments, will be described in detail. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context. When a portion “includes” an element, another element may be further included, rather than excluding the existence of the other element, unless otherwise described. Sizes or thicknesses of components in the drawings may be arbitrarily exaggerated for convenience of explanation. Further, when a certain material layer is described as being arranged or provided on a substrate or another layer, the material layer may be in contact with the other layer, or there may be a third layer between the material layer and the other layer. In embodiments, materials constituting each layer are provided merely as an example, and other materials may also be used.

Moreover, the terms “part,” “module,” etc. refer to a unit processing at least one function or operation, and may be implemented by a hardware, a software, or a combination thereof.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail. Furthermore, the connecting lines, or connectors shown in the various figures presented are intended to represent exemplary functional relations and/or physical or logical couplings between the various elements. It should be noted that many alternative or additional functional relations, physical connections or logical connections may be present in a practical device.

The use of the terms “a” and “an” and “the” and similar referents in the context of describing embodiments (especially in the context of the following claims) are to be construed to cover both the singular and the plural.

Also, the steps of all methods described herein can be performed in any suitable order unless otherwise indicated herein or otherwise clearly contradicted by context. The use of any and all exemplary languages (e.g., “such as”) provided herein, are intended merely to better illuminate the technical ideas and does not pose a limitation on the scope of rights unless otherwise claimed.

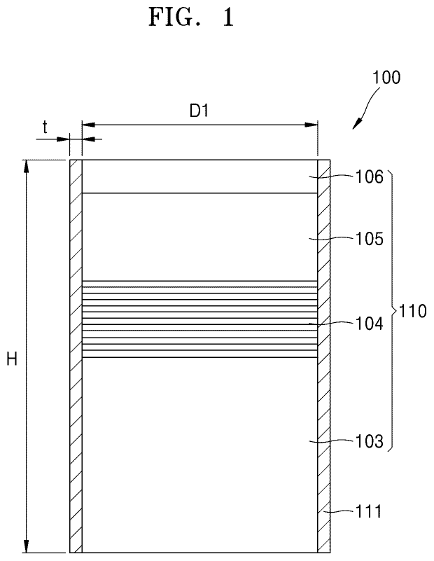

FIG. 1 is a diagram of a semiconductor light-emitting device according to an example embodiment.

A semiconductor light-emitting device 100 may include a light-emitting stack structure 110 configured to emit light and a first passivation film 111 provided on a side surface (or side wall) of the light-emitting stack structure 110. The light-emitting stack structure 110 may include a first semiconductor layer 103, an active layer 104 provided on the first semiconductor layer 103, and a second semiconductor layer 105 provided on the active layer 104. The light-emitting stack structure 110 may further include a transparent electrode 106 provided on the second semiconductor layer 105. In addition, although it is not shown in the drawings, the light-emitting stack structure 110 may further include a transparent contact layer provided between the second semiconductor layer 105 and the transparent electrode 106.

The first semiconductor layer 103 and the second semiconductor layer 105 may include a Group II-VI or Group III-V compound semiconductor material. The first semiconductor layer 103 and the second semiconductor layer 105 may provide electrons or holes to the active layer 104. To this end, the first semiconductor layer 103 may be doped with an n-type dopant or a p-type dopant, and the second semiconductor layer 105 may be doped with a dopant having a conductivity type electrically opposite to that of the first semiconductor layer 103. For example, when the first semiconductor layer 103 is doped with an n-type dopant, the second semiconductor layer 105 may be doped with a p-type dopant, or when the first semiconductor layer 103 is doped with a p-type dopant, the second semiconductor layer 105 may be doped with an n-type dopant. When the first semiconductor layer 103 or the second semiconductor layer 105 is doped with an n-type dopant, for example, Si, Ge, or Sn may be used as a dopant, and when the first semiconductor layer 103 or the second semiconductor layer 105 is doped with a p-type dopant, for example, Mg, Zn, Ca, Se, or Ba may be used as a dopant. The first semiconductor layer 103 or second semiconductor layer 105 doped with an n-type dopant may provide electrons to the active layer 104, and the second semiconductor layer 105 or first semiconductor layer 103 doped with a p-type dopant may provide holes to the active layer 104.

The first semiconductor layer 103 may include an n-type semiconductor of Group III-V, such as n-GaN. The second semiconductor layer 105 may include a p-type semiconductor of Group III-V, such as p-GaN. The first semiconductor layer 103 and the second semiconductor layer 105 may have a single-layer or multi-layer structure.

The active layer 104 may include a nitride semiconductor. For example, the active layer 104 may include a GaN-based material. In this case, the active layer 104 may include an undoped GaN-based material or a GaN-based material doped with certain impurities. For example, the active layer 104 may include at least one of InAlGaN, GaN, AlGaN, and InGaN. Alternatively, the active layer 104 may include at least one of AlN, InN, and AlGaInP.

The active layer 104 may have a quantum well structure in which a quantum well is provided between barriers. The electrons and holes provided from the first semiconductor layer 103 and the second semiconductor layer 105 may recombine in the quantum well in the active layer 104, thereby generating light. A wavelength of light generated in the active layer 104 may be determined according to an energy band gap of a material constituting the quantum well in the active layer 104. The active layer 104 may include only one quantum well or may have a multi-quantum well (MQW) structure in which a plurality of quantum wells and a plurality of barriers are alternately arranged. A thickness of the active layer 104 or a number of quantum wells in the active layer 104 may be appropriately selected in consideration of a driving voltage and a luminescence efficiency of the semiconductor light-emitting device 100. When the active layer 104 has a multi-quantum well structure, for example, a quantum well structure including InGaN/GaN or AlGaN/GaN may be included.

For example, the light-emitting stack structure 110 may be configured to emit light having a blue wavelength. The light-emitting stack structure 110 may emit, for example, light having a peak wavelength of about 400 nm to about 550 nm. The emission wavelength of the light-emitting stack structure 110 may be controlled by controlling a material composition of the active layer 104. When the active layer 104 includes indium (In), the greater the content of indium in the active layer 104 is, the longer the wavelength of light emitted from the active layer 104 may be. For example, when the indium content of the active layer 104 is about 15%, the active layer 104 may emit blue light of about 450 nm, when the indium content of the active layer 104 is about 25%, the active layer 104 may emit green light of about 520 nm, and when the indium content of the active layer 104 is about 35%, the active layer 104 may emit red light of about 630 nm. However, the foregoing is only an example, and various configurations may be applied for emission of blue light.

When the semiconductor light-emitting device 100 has a very small size, such as a nano size or a micro size, an external quantum efficiency (EQE) and an internal quantum efficiency (IQE) of the active layer 104 may decrease. In addition, a defect due to a lattice mismatch may increase as the In content of the active layer 104 increases. In the semiconductor light-emitting device 100, according to an example embodiment for example, by controlling the composition of In in the material of the active layer 104, the wavelength of light emitted from the light-emitting stack structure 110 may be adjusted to about 400 nm to about 550 nm.

The semiconductor light-emitting device 100 may have a nano rod shape having a very small size such as a nano size or a micro size. However, the semiconductor light-emitting device 100 is not limited to the above and, for example, may have a micro chip structure.

The semiconductor light-emitting device 100 may have a cylindrical structure. However, the shape of the semiconductor light-emitting device 100 is not limited thereto and may include various rod structures such as a tetragonal pillar, a pentagonal pillar, and a hexagonal pillar. The first semiconductor layer 103 may have a relatively great height compared to the active layer 104 or the second semiconductor layer 105. A height H of the first semiconductor layer 103 may be relatively greater than a diameter D1 thereof. For example, the semiconductor light-emitting device 100 may have the diameter D1 of 100 μm or less. For example, the diameter D1 of the semiconductor light-emitting device 100 may be 50 μm or less. Alternatively, the diameter D1 of the semiconductor light-emitting device 100 may be in a range of about 0.5 μm to about 2 μm. Here, the diameter D1 may represent a maximum diameter when the diameter of the semiconductor light-emitting device 100 is not uniform. The semiconductor light-emitting device 100 may have a generally uniform diameter in a height direction. However, the semiconductor light-emitting device 100 is not limited thereto.

When a length between a lower surface of the first semiconductor layer 103 and an upper surface of the second semiconductor layer 105 is the height H of the semiconductor light-emitting device 100, the height H may be in a range of about 1 μm to about 20 μm. Alternatively, the height H may be in a range of about 2 μm to about 10 μm. In addition, the semiconductor light-emitting device 100 may have, for example, a great aspect ratio of 4 or more. For example, the diameter D1 of the semiconductor light-emitting device 100 may be selected to be about 600 nm, and the height H may be selected to be about 5 μm. In this case, the aspect ratio of the semiconductor light-emitting device 100 may be slightly greater than 8.

When the light-emitting stack structure 110 having a large aspect ratio is manufactured in a small size, a surface defect of the active layer 104 may increase as a surface-to-volume ratio increases. In other words, a surface defect due to a dangling bond may occur on an outer surface of the active layer 104, and when the surface-to-volume ratio increases, resulting in an increased dangling bond, the surface defect may also increase. Such surface defect may interfere with a flow of current, thereby decreasing the luminescence efficiency of the active layer 104. The smaller the semiconductor light-emitting device 100 is, the lower the luminescence efficiency may be.

The semiconductor light-emitting device 100 may include the first passivation film 111 on the side surface of the light-emitting stack structure 110 to increase the luminescence efficiency. The first passivation film 111 may include a tantalum oxide (TaxOy). The composition ratio of the tantalum oxide in the first passivation film 111 may have a range of 0.1≤y/x≤10.

The tantalum oxide may include Ta₂O₃ or Ta₂O₅. The first passivation film 111 may be in direct contact with the light-emitting stack structure 110.

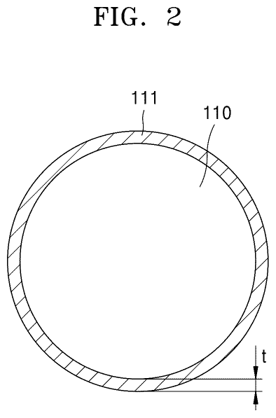

FIG. 2 is a plan view of the semiconductor light-emitting device 100 shown in FIG. 1.

The first passivation film 111 may not only increase the luminescence efficiency of the light-emitting stack structure 110 but also protect the light-emitting stack structure 110 from an external physical and/or chemical shock and prevent the leakage of current by insulating the light-emitting stack structure 110. To this end, as shown in FIG. 2, the first passivation film 111 may completely cover (or surround) the side surface of the light-emitting stack structure 110. The first passivation film 111 may have a ring shape in a plan view and may have a cylindrical shape as a whole (or in a perspective view). Although FIG. 2 illustrates an example in which the light-emitting stack structure 110 is circular; however, the disclosure is not necessarily limited thereto. A thickness t of the first passivation film 111 in a diameter direction of the semiconductor light-emitting device 100, i.e., a distance between an inner side surface and an outer side surface of the first passivation film 111 may be in a range of about 1 nm to about 50 nm. Alternatively, the thickness of the first passivation film 111 may be in a range of about 1 nm to about 40 nm.

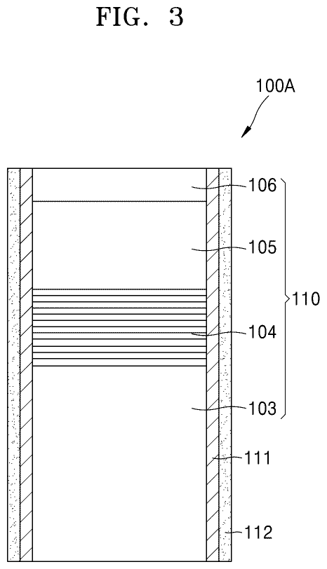

FIG. 3 illustrates an example in which a semiconductor light-emitting device includes a second passivation film 112 according to an example embodiment.

A semiconductor light-emitting device 100A may further include the second passivation film 112 provided on the first passivation film 111. In FIG. 3, elements using the same reference numerals as in FIG. 1 are substantially the same as the elements of FIG. 1, and thus, detailed descriptions thereof are omitted. The second passivation film 112 may include at least one of SiO₂, SiN, SiCN, SiOC, SiON, SiOCN, HfOₓ, AlOₓ, ZrOₓ, AlN, AlOₓN_{y}, Ta₂O₃, or Ta₂O₅. The second passivation film 112 may include a single layer or a plurality of layers. The second passivation film 112 may include, for example, one to five layers. The thickness of the second passivation film 112 may be in a range of about 1 nm to about 15 nm.

The second passivation film 112 may include an amorphous material. Alternatively, the second passivation film 112 may be formed by crystal-growing a material having a crystal structure similar to that of the active layer 104. In this case, the second passivation film 112 may have an epitaxial relationship with the active layer 104. The second passivation film 112 may include an insulating crystal material having the same crystal structure as the crystal structure of the active layer 104. The second passivation film 112 may have a lattice matching epitaxy relationship or a domain matching epitaxy relationship with the active layer 104. The lattice matching epitaxy relationship refers to a relationship in which a lattice constant of the second passivation film 112 is almost the same as a lattice constant of the active layer 104. In addition, the domain matching epitaxial relationship refers to a relationship in which the lattice constant of the second passivation film 112 is almost the same as an integer multiple of the lattice constant of the semiconductor light-emitting device 100A or the lattice constant of the semiconductor light-emitting device 100A is almost the same as an integer multiple of the lattice constant of the second passivation film 112. For example, a difference between a lattice constant m1 of the semiconductor light-emitting device 100A and a lattice constant m2 of the second passivation film 112 may be within +30% of the lattice constant m1. Then, as the dangling bonds on the outer surface of the active layer 104 are removed, the surface defect generated on the outer surface of the active layer 104 may be prevented. Therefore, the active layer 104 may avoid the surface defect, and the luminescence efficiency of the semiconductor light-emitting device 100A may be improved.

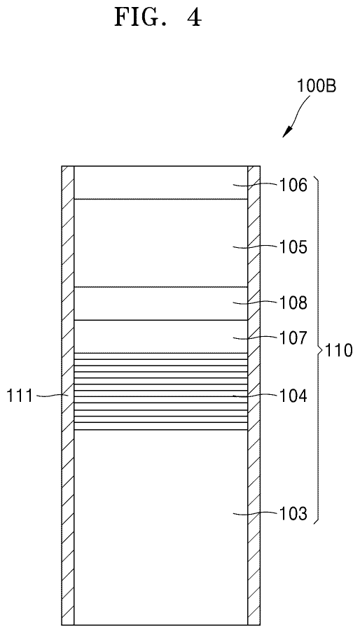

FIG. 4 is a diagram illustrating an example in which a semiconductor light-emitting device includes a superlattice layer and an electron blocking layer according to an example embodiment.

In a semiconductor light-emitting device 100B, a superlattice layer 107 may be further provided between the second semiconductor layer 104 and the active layer 104.

The superlattice layer 107 may include, for example, an InGaN/GaN superlattice layer, an AlN/GaN superlattice layer, or an AlₓIn_{y}Ga_{(1-x-y)}N/AlₓIn_{y}Ga_{(1-x-y)}N (0≤x, y≤1, x≠y) superlattice layer. The superlattice layer 107 may relieve current spreading and strain at a lower portion of the active layer 104. The superlattice layer 107 may have a structure in which two layers are alternately laminated, for example, the InGaN/GAN superlattice layer may include an InGaN layer and a GaN layer that are alternately arranged. The superlattice layer 107 may have a greater band gap than the active layer 104 so that light is not emitted from or absorbed by the superlattice layer 107. For example, the active layer 104 may include 10 pairs of In₁₅Ga₇₅N/GaN layers deposited at thicknesses of 5 nm/5 nm, and the superlattice layer 107 may include 30 pairs of In₅Ga₉₅N/GaN layers deposited at thicknesses of 1 nm/1 nm. The In content and thickness of the superlattice layer 107 may be respectively less than those of the active layer 104.

An electron blocking layer 108 may be further provided between the active layer 104 and the second semiconductor layer 105. The electron blocking layer 108 may include AlGaN, AlInN, or AlInGaN. The electron blocking layer 108 may have a thickness of 3 nm or more. The electron blocking layer 108 may prevent electron tunneling to efficiently prevent electron leakage.

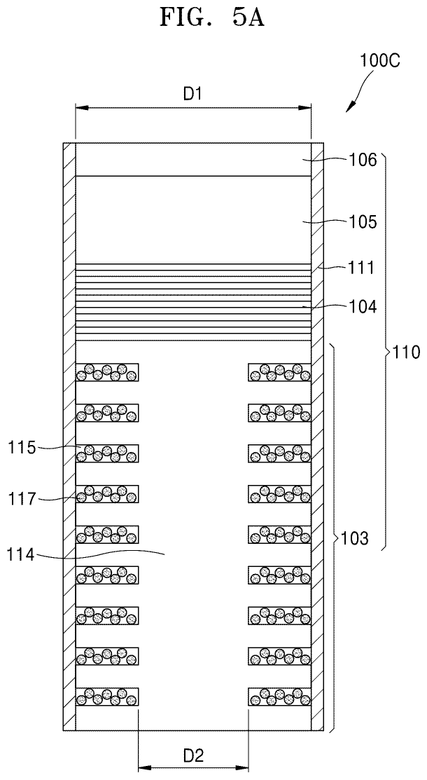

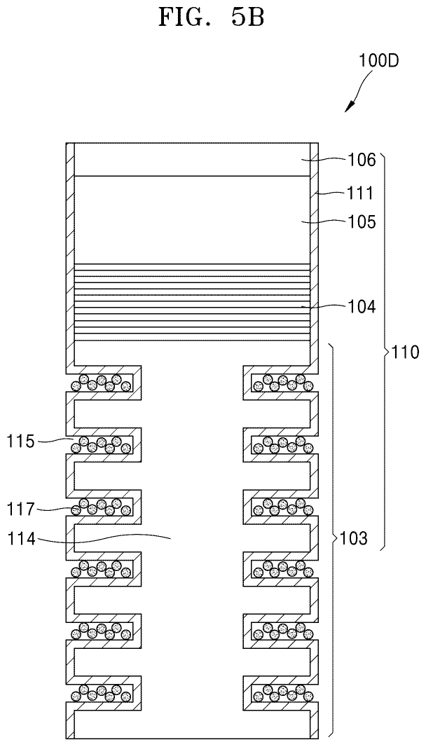

FIGS. 5A and 5B are diagrams each illustrating an example in which a semiconductor light-emitting device includes quantum dots according to example embodiments.

Referring to FIG. 5A, in a semiconductor light-emitting device 100C, the first semiconductor layer 103 may include a core rod 114 and a plurality of nanopores 115 open in an outward direction from the core rod 114. The core rod 114 may represent a central area of the first semiconductor layer 103 that does not include the nanopores 115. A diameter D2 of the core rod 114 may be in a range of ⅕ to ⅓ of the diameter D1 of the light-emitting stack structure 110. For example, the diameter of the core rod 114 may be in a range of about 120 nm to about 200 nm. The diameter D2 of the core rod 114 may represent a maximum diameter in any one transverse section of the first semiconductor layer 103, which is a cross-section cut in a certain way. In particular, the transverse section refers to a cross-section cut in a diameter direction of the semiconductor light-emitting device 100C in a region that includes the nanopores 115. The core rod 114 may have an approximately circular transverse section, and substantially, the transverse section of the core rod 114 may not be completely circular and may have an elliptical or uneven shape. In this case, the diameter D2 of the core rod 114 may represent a distance between the nanopores 115 facing each other in the transverse section, and may represent a maximum diameter of the core rod 114 in the transverse section.

The core rod 114 may function as a path through which a current supplied to the semiconductor light-emitting device 100C flows efficiently by securing an area having a certain diameter to improve electrical stability. In addition, the core rod 114 may be provided in the central area of the semiconductor light-emitting device 100C to provide structural stability.

The nanopores 115 may be open in the outward direction from the core rod 114. The nanopores 115 may be provided radially from the core rod 114 when seen from the transverse section of the first semiconductor layer 103. The nanopores 115 may be provided at an outer portion of the first semiconductor layer 103 with respect to the core rod 114. In addition, the nanopores 115 may have a shape in which a length in a diameter direction of the first semiconductor layer 103 is relatively longer than a length of the first semiconductor layer 103 in a direction perpendicular to the diameter direction. The nanopores 115 may be arranged apart from each other in a line in a height direction in a vertical section of the first semiconductor layer 103.

Quantum dots 117 may be dispersed in the plurality of nanopores 115. The quantum dot 117, i.e., a nano-sized inorganic substance, has an energy bandgap of a specific wavelength, and thus is able to convert colors by outputting light of different wavelengths when it has absorbed light having a higher energy than its energy bandgap. As the quantum dot 117 has a narrow emission wavelength band, color reproduction of a display apparatus may increase.

The quantum dot 117 may have a core-shell structure including a core portion and a shell portion, or a particle structure without a shell. The core-shell structure may include a single-shell structure and/or a multi-shell structure (e.g., a double-shell structure).

The quantum dot 117 may include a Group II-VI semiconductor, a Group III-V semiconductor, a Group IV-VI semiconductor, a Group IV semiconductor, and/or graphene quantum dots. The quantum dot 117 may include, for example, Cd, Se, Zn, S, and/or InP, and each quantum dot 117 may have a diameter less than or equal to tens of nanometers, for example, 10 nm or less. The quantum dot 117 may include, for example, a compound such as CdSe, CdTe, InP, InAs, InSb, PbSe, PbS, PbTe, AlAs, ZnS, ZnSe, ZnTe, graphene, etc. The quantum dot 117 may absorb light having a specific wavelength band and emit light having a wavelength band longer than the aforementioned specific wavelength band. A wavelength of light absorbed by the quantum dot 117 may change according to an energy bandgap of the quantum dot 117. An energy bandgap of the quantum dot 117 may change according to a material or a size of the quantum dot 117.

Referring to FIG. 5A, the first passivation film 111 may be provided along a side surface of the first semiconductor layer 103 and outside of the nanopores 115.

Referring to FIG. 5B, in a semiconductor light-emitting device 100D, the first passivation film 111 may be provided along the side surface of the first semiconductor layer 103 and inside of the nanopores 115.

In the semiconductor light-emitting devices 100C and 100D, as a deposition may be performed at a relatively low temperature, the semiconductor light-emitting devices 100C and 100D may be manufactured without damaging the quantum dots 117 which are vulnerable to a relatively high temperature. In the semiconductor light-emitting devices 100C and 100D, the luminescence efficiency may be improved based on the quantum dots 117 and the first passivation film 111.

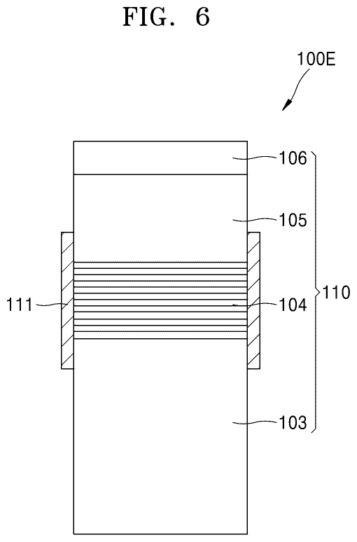

FIG. 6 is a diagram illustrating an example in which a first passivation film is provided on a portion of a side surface of a semiconductor light-emitting device according to an example embodiment. FIG. 6 illustrates an example in which a location of the first passivation film 111 is changed compared with the semiconductor light-emitting device of FIG. 1. In the above example embodiment(s), it has been illustrated that the first passivation film 111 covers (or surrounds) the side surfaces (or side surfaces) of the first semiconductor layer 103, the active layer 104, and the second semiconductor layer 105; however, the disclosure is not limited thereto. Referring to FIG. 6, in a semiconductor light-emitting device 100E, the first passivation film 111 may be provided to cover (or surround) only a portion of the side surface of the light-emitting stack structure 110. The first passivation film 111 may only surround the active layer 104 or only a portion of the side surface of the light-emitting stack structure 110 including at least the active layer 104.

The semiconductor light-emitting devices 100, 100A, 100B, 100C, and 100D according to example embodiments may include the first passivation film 111 including a tantalum oxide to improve the luminescence efficiency of blue light having a peak wavelength of about 400 nm to about 550 nm.

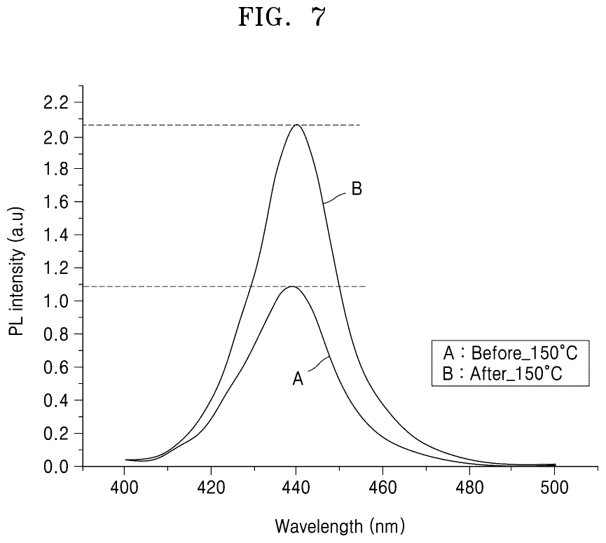

FIG. 7 illustrate graphs showing a change in a photo luminescence (PL) intensity according to a wavelength in a semiconductor light-emitting device according to an example embodiment and a semiconductor light-emitting device according to a comparative example, respectively.

(A) represents a case in which a semiconductor light-emitting device does not include a first passivation film, and (B) represents a case where the first passivation film 111 including TaO is deposited at approximately 150° C. (B) shows a relatively higher PL intensity at a peak wavelength of 440 nm than (A).

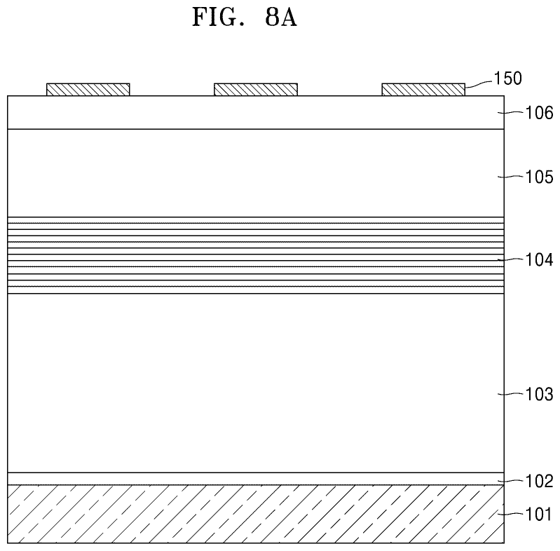

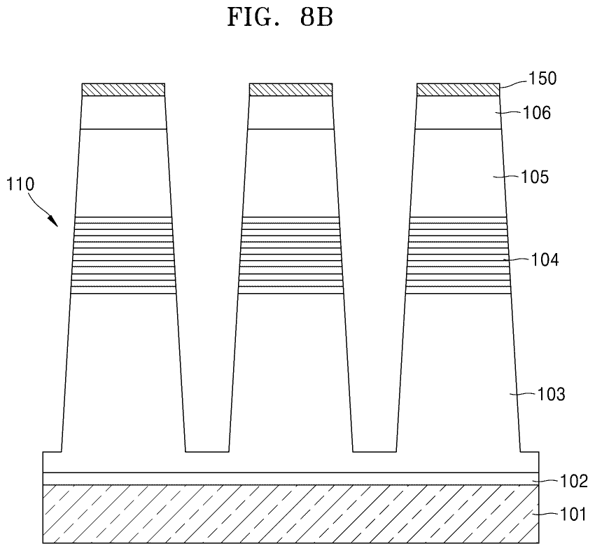

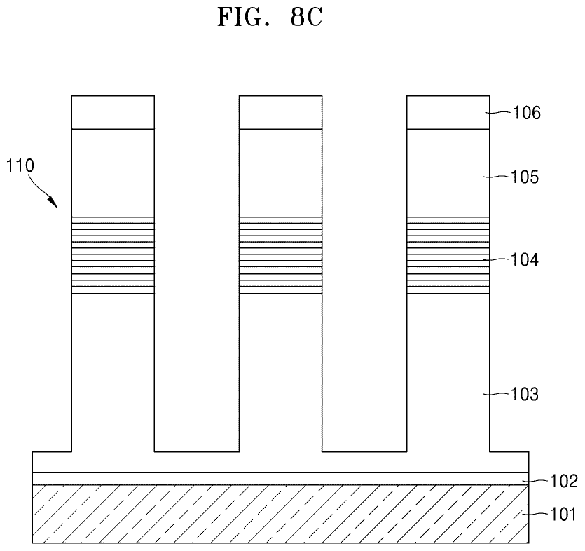

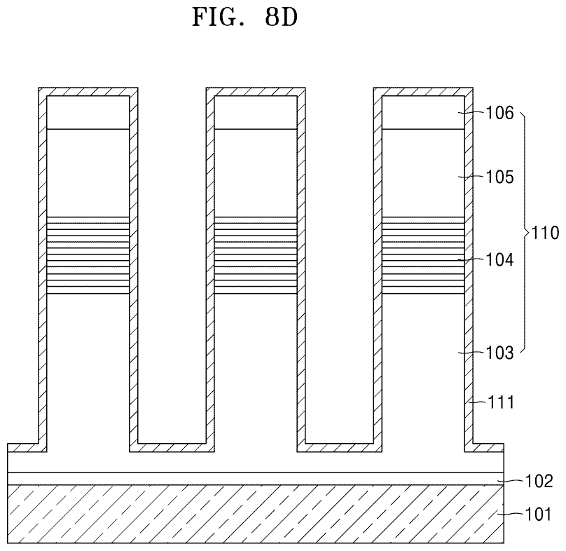

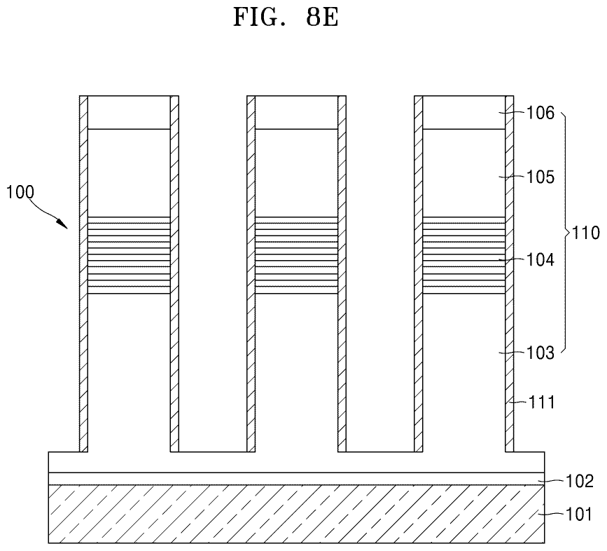

Hereinafter, a method of manufacturing a semiconductor light-emitting device according to one or more example embodiments will be described with reference to FIGS. 8A to 10.

Referring to FIG. 8A, the first semiconductor layer 103, the active layer 104, and the second semiconductor layer 105 may be formed on a substrate 101. The first semiconductor layer 103 may be an n-type semiconductor layer and may include, for example, an n-type GaN. The active layer 104 may have a single quantum well structure or a multi-quantum well structure. The active layer 104 may include at least one of InAlGaN, GaN, AlGaN, and InGaN. Alternatively, the active layer 104 may include at least one of AlN, InN, and AlGaInP. The active layer 104 may be configured to emit light having a peak wavelength of about 400 nm to about 550 nm.

The second semiconductor layer 105 may be a p-type semiconductor layer and may include, for example, a p-type GaN. A buffer layer 102 may be formed between the substrate 101 and the first semiconductor layer 103.

The substrate 101 and the buffer layer 102 may include a Group II-VI or a Group III-V compound semiconductor material. Alternatively, the substrate 101 may include a silicon substrate. The substrate 101 and the buffer layer 102 may be doped with a dopant having the same conductivity type as the first semiconductor layer 103. For example, when the first semiconductor layer 103 is doped with an n-type dopant, the substrate 101 and the buffer layer 102 may include n-GaAs. The substrate 101 may be doped at a lower concentration than the buffer layer 102, and the buffer layer 102 may be doped at a higher concentration than the substrate 101. Although it is not shown in FIG. 8A, a contact layer for an ohmic contact may be further provided between the buffer layer 102 and the first semiconductor layer 103. The contact layer provided between the buffer layer 102 and the first semiconductor layer 103 may be doped with a dopant having the same conductivity type as the first semiconductor layer 103, and may be doped at a higher concentration than the doping concentrations of the buffer layer 102 and the first semiconductor layer 103.

The transparent electrode 106 may be further formed on the second semiconductor layer 105. In addition, the contact layer may be further provided between the second semiconductor layer 105 and the transparent electrode 106. For example, the contact layer may include GaInP or GaAs, or may include both GaInP and GaAs. The contact layer may provide an ohmic contact. The contact layer may be doped with a dopant having the same conductivity type as the second semiconductor layer 105. For example, when the second semiconductor layer 105 is doped with a p-type dopant, the contact layer may also be doped with a p-type dopant.

The active layer 104 may include at least one of InAlGaN, GaN, AlGaN, and InGaN. Alternatively, the active layer 104 may include at least one of AlN, InN, and AlGaInP. The composition ratio of the active layer 104 may be controlled to generate blue light having a peak wavelength of about 400 nm to about 450 nm. For example, the active layer 104 may include AlGaInP. AlGaInP of the active layer 104 may not be doped. The active layer 104 may include a barrier and a quantum well, and to this end, the content of Al in AlGaInP may vary. For example, the Al content may be higher in the barrier than in the quantum well. In addition, compared to the first and second semiconductor layers 103 and 105, the content of Al may be the greatest in the first and second semiconductor layers 103 and 105, the content of Al in the barrier in the active layer 104 is the second greatest, and the content of Al may be the least in quantum well in the active layer 104. Then, in a conduction band, the energy level of the first and second semiconductor layers 103 and 105 may be the highest, and the energy level of the barrier in the active layer 104 may be the second highest, and the energy level of the quantum well in the active layer 104 may be the lowest. Even when other semiconductor materials are used in addition to AlGaInP, the active layer 104 may be formed to include a barrier and a quantum well by adjusting the composition of the material.

After forming the transparent electrode 106, a hard mask 150 including a plurality of openings arranged at regular intervals may be formed on the transparent electrode 106. For example, after the material of the hard mask 150 is formed on the entire upper surface of the transparent electrode 106, the hard mask 150 may be formed by patterning the material of the hard mask 150 using a lithography method to include a plurality of openings arranged at regular intervals. The hard mask 150 may be formed, for example, as a SiO₂ single layer or a SiO₂/Al double layer. Although it is not shown in the cross-sectional view of FIG. 8A the hard mask 150 as viewed from above (or in a plan view) may have a plurality of openings arranged two-dimensionally.

Referring to FIG. 8B, regions that are not covered with the hard mask 150 may be eliminated by etching using a dry etching method. For example, by sequentially etching and removing the transparent electrode 106, the second semiconductor layer 105, the active layer 104, and the first semiconductor layer 103 under the opening of the hard mask 150, the transparent electrode 106, the second semiconductor layer 105, the active layer 104, and the first semiconductor layer 103 may be patterned in the form of a plurality of nano rods. Accordingly, as shown in FIG. 8B, a plurality of light-emitting stack structures 110 each including the transparent electrode 106, the second semiconductor layer 105, the active layer 104, and the first semiconductor layer 103 may be formed at once on the substrate 101 and the buffer layer 102. In FIG. 8B, although it is shown that a lower portion of the first semiconductor layer 103 remains partially, the disclosure is not limited thereto, and the etching may be performed until the buffer layer 102 is exposed. Then, the first semiconductor layer 103 may be completely etched to the lower portion thereof and the buffer layer 102 may remain entirely or partially.

The light-emitting stack structures 110 formed in FIG. 8B may have diameters gradually decreasing in the height direction from the first semiconductor layer 103 to the transparent electrode 106. Referring to FIG. 8C, for example, through wet etching using a KOH solution, the diameter of the light-emitting stack structures 110 may become uniform in the height direction. In this process, the hard mask 150 may also be removed.

Referring to FIG. 8D, the first passivation film 111 may be evenly formed on the surface of the light-emitting stack structure 110. To form the first passivation film 111, a passivation film material may be deposited n times (n is a natural number) by using, for example, an atomic layer deposition (ALD) method. The process of forming the first passivation film 111 will be described later.

Referring to FIG. 8E, the first passivation film 111 provided between adjacent light-emitting stack structures 110 and the first passivation film 111 on the upper surface of the light-emitting stack structure 110 may be removed. Then, only the first passivation film 111 surrounding the side surfaces of the plurality of light-emitting stack structures 110 may remain. Through the above method, a plurality of semiconductor light-emitting devices 100 may be formed at once on the substrate 101 and the buffer layer 102. Then, by removing the buffer layer 102, the plurality of semiconductor light-emitting devices 100 may be separated individually. Alternatively, the substrate 101 and the buffer layer 102 may be cut in a vertical direction and each of the semiconductor light-emitting devices 100 may be used in a state in which the substrate 101 and the buffer layer 102 are attached together on the semiconductor light-emitting device 100. Alternatively, the substrate 101 and the buffer layer 102 may be cut in the vertical direction such that two or more semiconductor light-emitting devices 100 remain, and the two or more semiconductor light-emitting devices 100 may be used together.

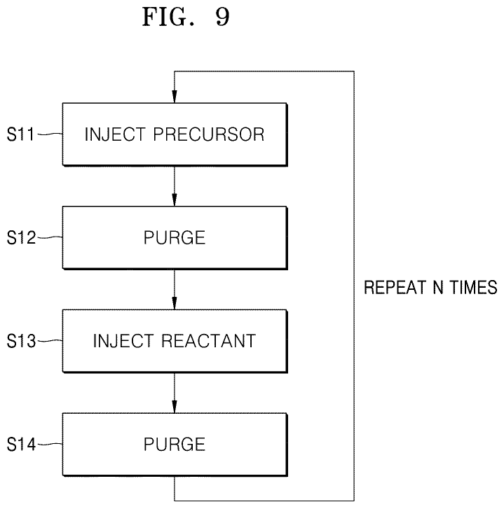

FIG. 9 is a flowchart illustrating a process of forming the first passivation film 111 according to an example embodiment. Referring to FIG. 9, the first passivation film 111 material may be deposited multiple times by using the ALD method.

The depositing of the first passivation film 111 may include injecting a precursor into a chamber (S11), purging (S12), injecting a reactant into the chamber and reacting the reactant with the precursor (S13), and purging (S14). S11, S12, S13, and S14 may be repeated n times (n is a natural number), for example, 1 to 100 times. Alternatively, n may include a range of 1 to 50 times. The precursor may include, for example, (t-butylimido)tris(diethylamido)tantalum (TBTDETa). The purging may include flowing Ar or N₂ gas into a chamber to remove surplus precursors and reaction by-products inside the chamber. The reactant may include, for example, O₂ or ozone. The injecting of the reactant may include an O₂ plasma process. In other words, the depositing of the first passivation film may be performed by a plasma enhanced (PE) ALD method. Or, the injecting of the reactant may include a thermal ozone process. In other words, the depositing of the first passivation film may be performed by a thermal ALD method. The first passivation film 111 may be in an amorphous state.

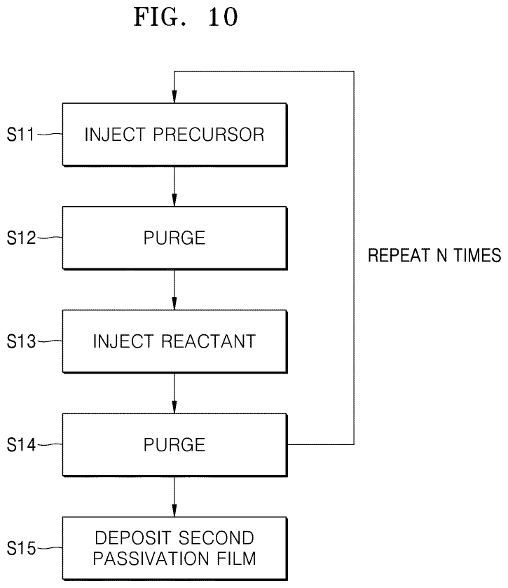

FIG. 10 is a flowchart illustrating a process of further depositing the second passivation film 112 on the first passivation film 111 according to an example embodiment. After repeating the process of depositing the first passivation film material (S11, S12, S13, and S14) n times, the second passivation film 112 may be deposited on the first passivation film 111 (S15). The second passivation film 112 may include at least one of SiO₂, SiN, SiCN, SiOC, SiON, SiOCN, HfOₓ, AlOₓ, ZrOₓ, AlN, AlOₓN_{y}, Ta₂O₃, and Ta₂O₅. The second passivation film 112 may be formed by, for example, depositing a second passivation film material several times through the ALD method. The second passivation film 112 may include an amorphous material.

According to this method according to an example embodiment, it may be possible to form the first passivation film 111 on the surface (e.g., side surface) of the light-emitting stack structure 110 while minimizing the damage of the light-emitting stack structure 110.

As described above, in the method of manufacturing the semiconductor device according to an example embodiment, the first passivation film including a tantalum oxide film may be manufactured by using the ALD process.

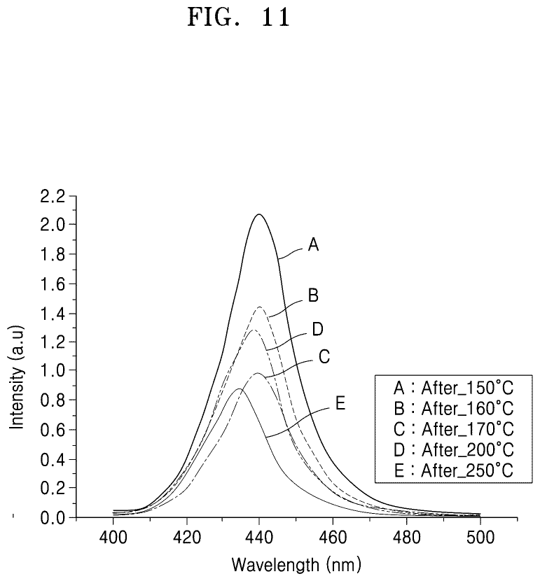

FIG. 11 illustrates graphs showing a change in a PL intensity according to a wavelength when the first passivation film 111 is applied according to example embodiments. (A) represents a case in which the first passivation film 111 is deposited at 150° C., (B) represents a case in which the deposition is performed at 160° C., (C) represents a case in which the deposition is performed at 170° C., (D) represents a case in which the deposition is performed at 200° C., and (E) represents a case in which the deposition is performed at 250° C. Referring to FIG. 11, the PL intensity changed according to the deposition temperature of the first passivation film 111. The deposition of the first passivation film 111 may be performed in a temperature range of 250° C. or less. For example, the deposition of the first passivation film 111 may be performed in a temperature range of 120° C. to about 250° C. As the deposition of the first passivation film 111 is performed at a temperature lower than 250° C., the quantum dots 117 as described with reference to FIGS. 5A and 5B may not be damaged.

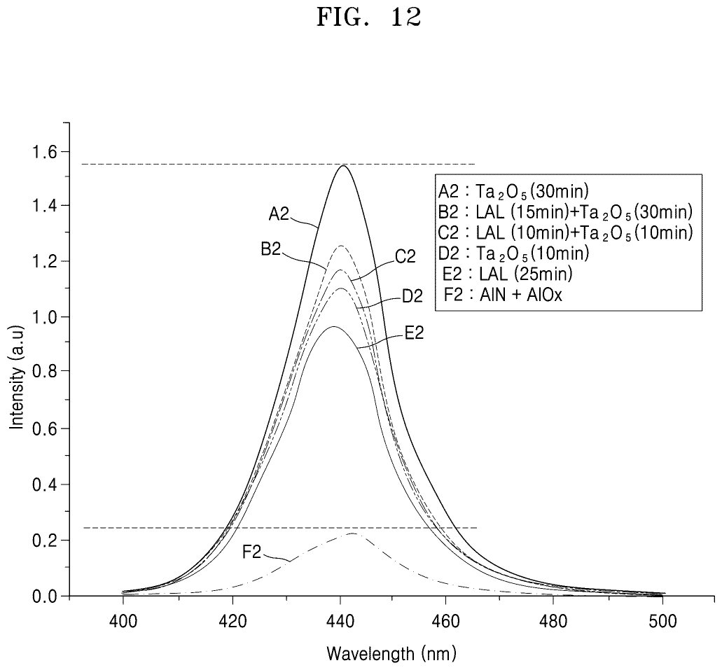

FIG. 12 illustrate graphs showing a comparison of PL intensities according to a wavelength between a semiconductor light-emitting device including a Ta₂O₅ passivation film according to example embodiments and a semiconductor light-emitting device including an AlN film and an AlOx film according to a comparative example.

(A2) represents a case in which a Ta₂O₅ passivation film is deposited for 30 minutes, (B2) represents a case in which LAL etching is performed for 15 minutes, and a Ta₂O₅ passivation film is deposited for 30 minutes, (C2) represents a case in which LAL etching is performed for 10 minutes, and a Ta₂O₅ passivation film is deposited for 10 minutes, (D2) represents a case in which a Ta₂O₅ passivation film is deposited for 10 minutes, (E2) represents a case in which LAL etching is performed for 25 minutes, and (F2) represents a case in which an AlN film and an AlOx film are included as a passivation film. A2, B2, C2, D2, and E2 all showed higher PL intensities than F2 at a wavelength of about 440 nm. The LAL solution refers to a chemical mixture of ammonium fluoride (NH4F) and hydrofluoric acid (HF) and is mainly used in silicon dioxide etching.

As described above, the semiconductor light-emitting device according to example embodiments may emit light having a peak wavelength of about 400 nm to about 550 nm, and the luminescence efficiency may be increased based on the first passivation film. Using the above characteristics, the semiconductor light-emitting device according to example embodiments may be applied to various electronic apparatuses.

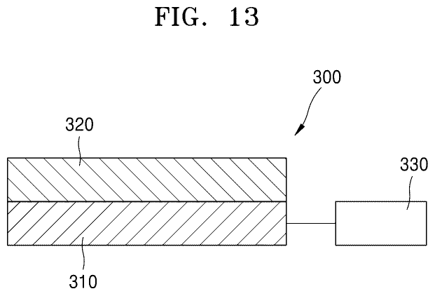

FIG. 13 is a diagram of a display apparatus according to an example embodiment. The display apparatus 300 may include a display substrate 310, which includes a driver circuit; an array layer 320 provided on the display substrate 310; and a controller 330 configured to input an image signal into the display substrate 310. The driver circuit may include at least one transistor and at least one capacitor. A plurality of semiconductor light-emitting devices may be arranged in the array layer 320.

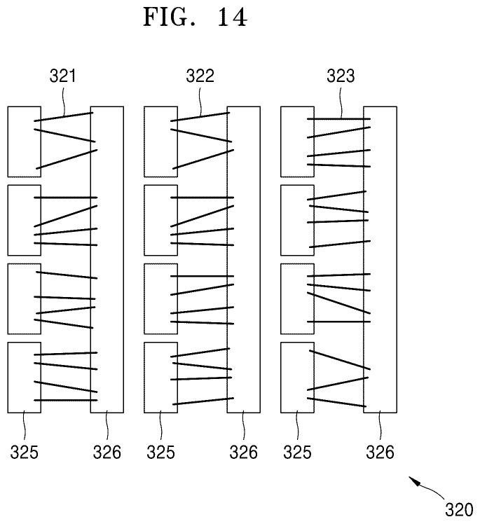

FIG. 14 illustrates the array layer 320 according to an example embodiment.

A first semiconductor light-emitting device 321, a second semiconductor light-emitting device 322, and a third semiconductor light-emitting device 323 may be included in the array layer 320 and may be used as light-emitting elements of pixels of next-generation display apparatuses. For example, the first semiconductor light-emitting device 321 may emit blue light, the second semiconductor light-emitting device 322 may emit green light, and the third semiconductor light-emitting device 323 may emit red light. Here, the semiconductor light-emitting devices 100, 100A, 100B, 100C, and 100D described with reference to FIGS. 1 to 6 may be applied as the third semiconductor light-emitting device 323. The array layer 320 may include a plurality of pixel electrodes 325, a common electrode 326 corresponding to the plurality of pixel electrodes 325, a plurality of first semiconductor light-emitting devices 321 connected between each of the pixel electrodes 325 and the common electrode 326, a plurality of semiconductor light-emitting devices 322, and a plurality of third semiconductor light-emitting devices 323.

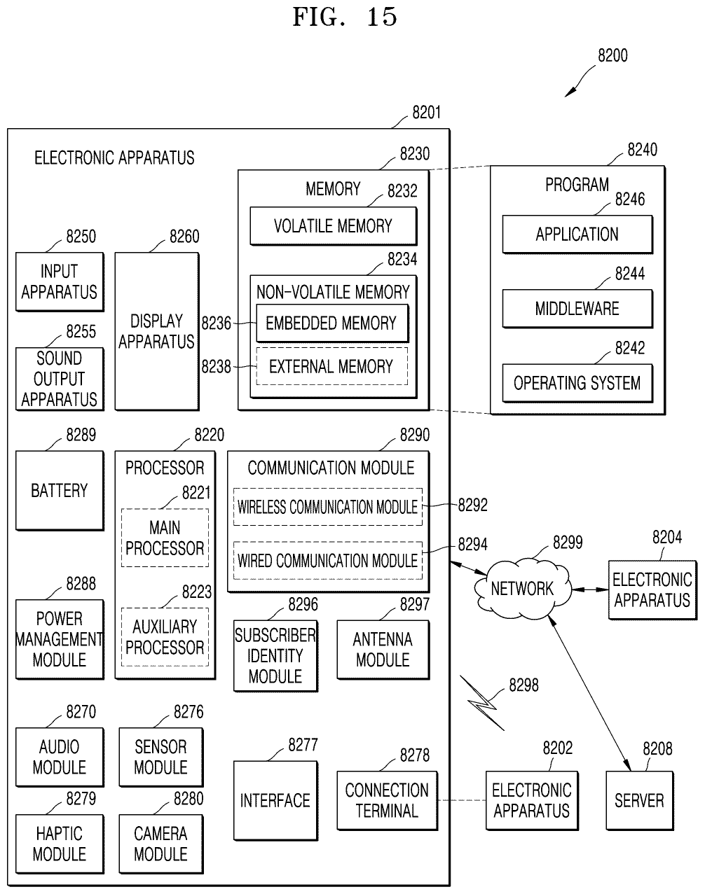

FIG. 15 is a block diagram of an electronic apparatus including a display apparatus according to an example embodiment.

Referring to FIG. 15, an electronic apparatus 8201 may be provided in a network environment 8200. In the network environment 8200, the electronic apparatus 8201 may communicate with another electronic apparatus 8202 through a first network 8298 (e.g., a short-range wireless communication network, etc.) or communicate with another electronic apparatus 8204 and/or a server 8208 through a second network 8299 (e.g., a long-distance wireless communication network, etc.). The electronic apparatus 8201 may communicate with the electronic apparatus 8204 through the server 8208. The electronic apparatus 8201 may include a processor 8220, a memory 8230, an input apparatus 8250, an audio output apparatus 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic apparatus 8201, some of constituent elements may be omitted or other constituent elements may be added. Some of the constituent elements may be implemented by one integrated circuit. For example, the sensor module 8276 (e.g., a fingerprint sensor, an iris sensor, an illuminance sensor, and the like) may be implemented by being embedded in the display apparatus 8260 (e.g., a display, and the like).

The processor 8220 may control one or a plurality of other constituent elements (e.g., hardware and software constituent elements, and the like) of the electronic apparatus 8201 connected to the processor 8220 by executing software (e.g., a program 8240, and the like), and perform various data processing or calculations. As part of the data processing or calculations, the processor 8220 may load, in a volatile memory 8232, commands and/or data received from other constituent elements (e.g., the sensor module 8276, the communication module 8290, and the like), process the command and/or data stored in the volatile memory 8232, and store result data in a non-volatile memory 8234. The non-volatile memory 8234 may include an internal memory 8236 and an external memory 8238. The processor 8220 may include a main processor 8221 (e.g., a central processing unit, an application processor, and the like) and an auxiliary processor 8223 (e.g., a graphics processing unit, an image signal processor, a sensor hub processor, a communication processor, and the like) that is operable independently of or together with the main processor 8221. The auxiliary processor 8223 may use less power than the main processor 8221 and may perform a specialized function.

Instead of the main processor 8221 when the main processor 8221 is in an inactive state (e.g., sleep state), or with the main processor 8221 when the main processor 8221 is in an active state (e.g., application execution state), the auxiliary processor 8223 may control functions and/or states related to some constituent elements (e.g., the display apparatus 8260, the sensor module 8276, the communication module 8290, and the like) of the constituent elements of the electronic apparatus 8201. The auxiliary processor 8223 (e.g., an image signal processor, a communication processor, and the like) may be implemented as a part of functionally related other constituent elements (e.g., the camera module 8280, the communication module 8290, and the like).

The memory 8230 may store various data needed by the constituent elements (e.g., the processor 8220, the sensor module 8276, and the like) of the electronic apparatus 8201. The data may include, for example, software (e.g., the program 8240, and the like) and input data and/or output data about commands related thereto. The memory 8230 may include the volatile memory 8232 and/or the non-volatile memory 8234.

The program 8240 may be stored in the memory 8230 as software, and may include an operating system 8242, middleware 8244, and/or an application 8246.

The input apparatus 8250 may receive commands and/or data to be used for constituent elements (e.g., the processor 8220, and the like) of the electronic apparatus 8201, from the outside (e.g., a user, and the like) of the electronic apparatus 8201. The input apparatus 8250 may include a remote controller, a microphone, a mouse, a keyboard, and/or a digital pen (e.g., a stylus pen, and the like).

The audio output apparatus 8255 may output an audio signal to the outside of the electronic apparatus 8201. The audio output apparatus 8255 may include a speaker and/or a receiver. The speaker may be used for general purposes such as multimedia playback or recording playback, and the receiver can be used to receive incoming calls. The receiver may be implemented by being coupled as a part of the speaker or by an independent separate device.

The display apparatus 8260 may visually provide information to the outside of the electronic apparatus 8201. The display apparatus 8260 may include a display, a hologram device, or a projector, and a control circuit to control a corresponding device. The display apparatus 8260 may include a display apparatus according to an example embodiment. The display apparatus 8260 may include a touch circuitry set to detect a touch and/or a sensor circuit (e.g., a pressure sensor, and the like) set to measure the strength of a force generated by the touch.

The audio module 8270 may convert sound into electrical signals or reversely electrical signals into sound. The audio module 8270 may obtain sound through the input apparatus 8250, or output sound through a speaker and/or a headphone of another electronic apparatus (e.g., the electronic apparatus 8202, and the like) connected to the audio output apparatus 8255 and/or the electronic apparatus 8201 in a wired or wireless manner.

The sensor module 8276 may detect an operation state (e.g., power, temperature, and the like) of the electronic apparatus 8201, or an external environment state (e.g., a user state, and the like), and generate an electrical signal and/or a data value corresponding to a detected state. The sensor module 8276 may include a gesture sensor, a gyro sensor, a barometric pressure sensor, a magnetic sensor, an acceleration sensor, a grip sensor, a proximity sensor, a color sensor, an IR sensor, a biometric sensor, a temperature sensor, a humidity sensor, and/or an illuminance sensor.

The interface 8277 may support one or more specified protocols used for the electronic apparatus 8201 to be connected to another electronic apparatus (e.g., the electronic apparatus 8202, and the like) in a wired or wireless manner. The interface 8277 may include a high definition multimedia interface (HDMI), a universal serial bus (USB) interface, an SD card interface, and/or an audio interface.

A connection terminal 8278 may include a connector for the electronic apparatus 8201 to be physically connected to another electronic apparatus (e.g., the electronic apparatus 8202, and the like). The connection terminal 8278 may include an HDMI connector, a USB connector, an SD card connector, and/or an audio connector (e.g., a headphone connector, and the like).

The haptic module 8279 may convert electrical signals into mechanical stimuli (e.g., vibrations, movements, and the like) or electrical stimuli that are perceivable by a user through tactile or motor sensations. The haptic module 8279 may include a motor, a piezoelectric device, and/or an electrical stimulation device.

The camera module 8280 may capture a still image and a video. The camera module 8280 may include a lens assembly including one or more lenses, image sensors, image signal processors, and/or flashes. The lens assembly included in the camera module 8280 may collect light emitted from a subject for image capturing.

The power management module 8288 may manage power supplied to the electronic apparatus 8201. The power management module 8388 may be implemented as a part of a power management integrated circuit (PMIC).

The battery 8289 may supply power to the constituent elements of the electronic apparatus 8201. The battery 8289 may include non-rechargeable primary cells, rechargeable secondary cells, and/or fuel cells.

The communication module 8290 may establish a wired communication channel and/or a wireless communication channel between the electronic apparatus 8201 and another electronic apparatus (e.g., the electronic apparatus 8202, the electronic apparatus 8204, the server 8208, and the like), and support a communication through an established communication channel. The communication module 8290 may be operated independent of the processor 8220 (e.g., the application processor, and the like), and may include one or more communication processors supporting a wired communication and/or a wireless communication. The communication module 8290 may include a wireless communication module 8292 (e.g., a cellular communication module, a short-range wireless communication module, a global navigation satellite system (GNSS) communication module, and the like), and/or a wired communication module 8294 (e.g., a local area network (LAN) communication module, a power line communication module, and the like). Among the above communication modules, a corresponding communication module may communicate with another electronic apparatus through the first network 8298 (e.g., a short-range communication network such as Bluetooth, WiFi Direct, or infrared data association (IrDA)) or the second network 8299 (e.g., a long-range communication network such as a cellular network, the Internet, or a computer network (e.g., LAN, WAN, and the like)). These various types of communication modules may be integrated into one constituent element (e.g., a single chip, and the like), or may be implemented as a plurality of separate constituent elements (e.g., multiple chips). The wireless communication module 8292 may verify and authenticate the electronic apparatus 8201 in a communication network such as the first network 8298 and/or the second network 8299 by using subscriber information (e.g., an international mobile subscriber identifier (IMSI), and the like) stored in the subscriber identification module 8296.

The antenna module 8297 may transmit signals and/or power to the outside (e.g., another electronic apparatus, and the like) or receive signals and/or power from the outside. An antenna may include an emitter formed in a conductive pattern on a substrate (e.g., a printed circuit board (PCB), and the like). The antenna module 8297 may include one or a plurality of antennas. When the antenna module 8297 includes a plurality of antennas, the communication module 8290 may select, from among the antennas, an appropriate antenna for a communication method used in a communication network such as the first network 8298 and/or the second network 8299. Signals and/or power may be transmitted or received between the communication module 8290 and another electronic apparatus through the selected antenna. Other parts (e.g., an RFIC, and the like) than the antenna may be included as a part of the antenna module 8297.

Some of the constituent elements may be connected to each other through a communication method between peripheral devices (e.g., a bus, general purpose input and output (GPIO), a serial peripheral interface (SPI), a mobile industry processor interface (MIPI), and the like) and may mutually exchange signals (e.g., commands, data, and the like).

The command or data may be transmitted or received between the electronic apparatus 8201 and the external electronic apparatus 8204 through the server 8208 connected to the second network 8299. The electronic apparatuses 8202 and 8204 may be of a type that is the same as or different from the electronic apparatus 8201. All or a part of operations executed in the electronic apparatus 8201 may be executed in one or more electronic apparatuses (e.g., 8202, 8204, and 8208). For example, when the electronic apparatus 8201 needs to perform a function or service, the electronic apparatus 8201 may request one or more electronic apparatuses to perform part of the whole of the function or service, instead of performing the function or service. The one or more electronic apparatuses receiving the request may perform additional function or service related to the request, and transmit a result of the performance to the electronic apparatus 8201. To this end, cloud computing, distributed computing, and/or client-server computing technology may be used.

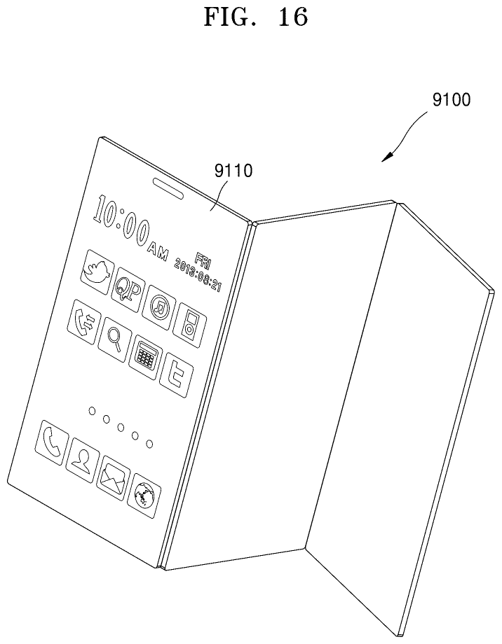

FIG. 16 shows an example in which an electronic apparatus according to an example embodiment is applied to a mobile apparatus. The mobile apparatus 9100 may include a display apparatus 9103, and the display apparatus 9103 may include display apparatuses according to an example embodiment. The display apparatus 9103 may include a foldable structure, for example, a multiple foldable structure.

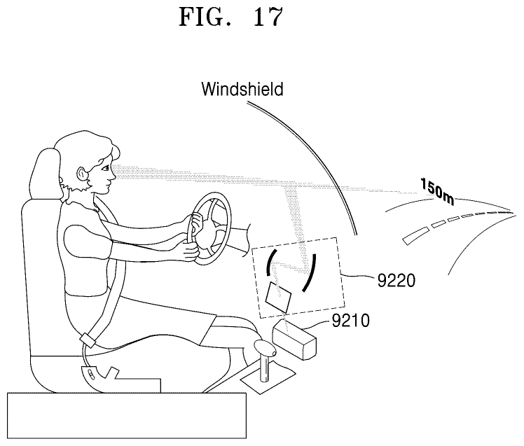

FIG. 17 shows an example in which a display apparatus according to an example embodiment is applied to a vehicle. The display apparatus may be a head-up display apparatus for vehicle 9200 and may include a display 9210 and an optical path change member 9220 configured to change an optical path so that a driver can see an image generated at the display 9210.

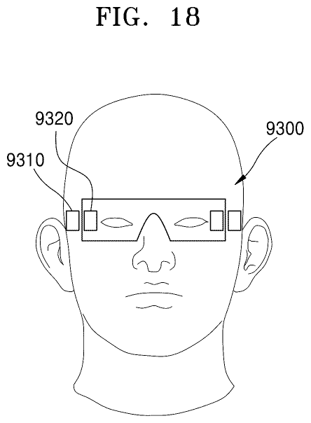

FIG. 18 shows an example in which a display apparatus according to an example embodiment is applied to augmented reality glasses or virtual reality glasses. The augmented reality glasses 9300 may include a projection system 9310 configured to form an image and an element configured to guide the image from the projection system 9310 to user's eyes. The projection system 9310 may include a display apparatus according to an example embodiment.

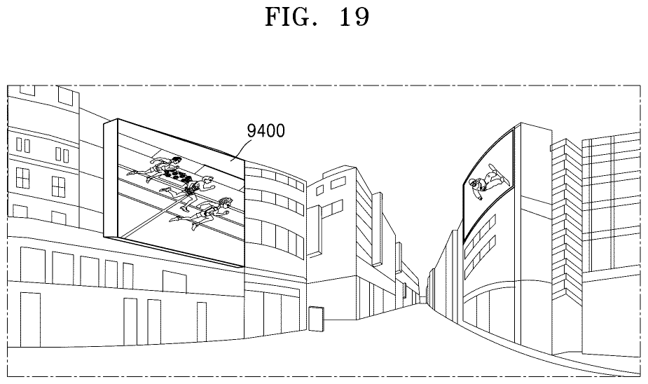

FIG. 19 illustrates an example in which a display apparatus according to an example embodiment is applied to a large signage. A signage 9400 may be used in outdoor advertising using a digital information display, and may control contents, etc. of an advertisement through a network. The signage 9400 may be implemented by, for example, the electronic apparatus described with reference to FIG. 15.

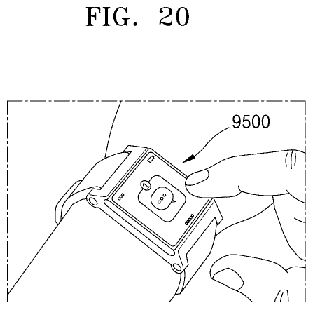

FIG. 20 is a diagram illustrating an example in which a display apparatus according to an example embodiment is applied to a wearable display. The wearable display 9500 may include a display apparatus according to an example embodiment and may be implemented through the electronic by described with reference to FIG. 15.

The display apparatus according to an example embodiment may also be applied to various products such as rollable TV, stretchable display, etc.

The semiconductor light-emitting device and the display apparatus including the semiconductor light-emitting device according to an example embodiment may be configured to emit light having a wavelength of about 400 nm to about 550 nm and may include a passivation film including a tantalum oxide (TaO), thereby increasing the PL intensity. As the semiconductor light-emitting device emitting light of blue wavelength is miniaturized, the luminescence efficiency may decreases. However, by including the passivation film, the luminescence efficiency may increase. The manufacturing method of the semiconductor light-emitting device described above may provide a method of depositing the tantalum oxide passivation film on the light-emitting stack structure.

It should be understood that example embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims and their equivalents.

What is claimed is:

1. A semiconductor light-emitting device, comprising:
a light-emitting stack structure including a first semiconductor layer, an active layer provided on the first semiconductor layer, and a second semiconductor layer provided on the active layer; and
a first passivation film provided on a side surface of the light-emitting stack structure,
wherein the light-emitting stack structure is configured to emit light having an emission peak wavelength in a range of about 400 nm to about 550 nm, and
wherein the first passivation film includes a tantalum oxide (TaxOy), and a composition ratio of the tantalum oxide of the first passivation film has a range of 0.1≤y/x≤10.

2. The semiconductor light-emitting device of claim 1, wherein a thickness of the first passivation film is in a range of about 1 nm to about 50 nm.

3. The semiconductor light-emitting device of claim 1, wherein the first passivation film includes Ta₂O₃ or Ta₂O₅.

4. The semiconductor light-emitting device of claim 1, further comprising a second passivation film provided on the first passivation film,
wherein the second passivation film includes at least one of SiO₂, SiN, SiCN, SiOC, SiON, SiOCN, HfOₓ, AlOₓ, ZrOₓ, AlN, AlOₓN_{y}, Ta₂O₃, or Ta₂O₅.

5. The semiconductor light-emitting device of claim 4, wherein the second passivation film is stacked in one to five layers.

6. The semiconductor light-emitting device of claim 4, wherein the second passivation film includes an amorphous material.

7. The semiconductor light-emitting device of claim 4, wherein the second passivation film has a thickness in a range of about 1 nm to about 15 nm.

8. The semiconductor light-emitting device of claim 1, wherein the first semiconductor layer includes a core rod, a plurality of nanopores open in an outward direction from the core rod, and quantum dots dispersed in the plurality of nanopores.

9. The semiconductor light-emitting device of claim 8, wherein the plurality of nanopores are arranged radially from the core rod in a transverse section of the first semiconductor layer.

10. The semiconductor light-emitting device of claim 9, wherein a diameter of the core rod is in a range of about ⅓ to about ⅕ of a diameter of the light-emitting stack structure.

11. The semiconductor light-emitting device of claim 1, wherein the semiconductor light-emitting device has a diameter in a range of about 0.5 μm to about 2 μm.

12. The semiconductor light-emitting device of claim 1, wherein the semiconductor light-emitting device has a height in a range of about 2 μm to about 7 μm.

13. A display apparatus comprising:
a plurality of pixel electrodes;
a common electrode corresponding to the plurality of pixel electrodes;
a plurality of semiconductor light-emitting devices connected between each pixel electrode of the plurality of pixel electrodes and the common electrode; and
a driver circuit layer configured to drive the plurality of semiconductor light-emitting devices,
wherein each semiconductor light-emitting device of the plurality of semiconductor light-emitting devices comprises:
a light-emitting stack structure including a first semiconductor layer, an active layer provided on the first semiconductor layer, and a second semiconductor layer provided on the active layer; and
a first passivation film provided a side surface of the light-emitting stack structure,
wherein the light-emitting stack structure is configured to emit light having an emission peak wavelength in a range of about 400 nm to about 550 nm, and
wherein the first passivation film includes a tantalum oxide (TaxOy), and a composition ratio of the tantalum oxide of the first passivation film has a range of 0.1≤y/x≤10.

14. The display apparatus of claim 13, wherein a thickness of the first passivation film is in a range of about 1 nm to about 50 nm.

15. The display apparatus of claim 13, wherein the first passivation film includes Ta₂O₃ or Ta₂O₅.

16. The display apparatus of claim 13, wherein each semiconductor light-emitting device further comprises a second passivation film provided on the first passivation film, and
wherein the second passivation film includes at least one of SiO₂, SiN, SiCN, SiOC, SiON, SiOCN, HfOₓ, AlOₓ, ZrOₓ, AlN, AlOₓN_{y}, Ta₂O₃, or Ta₂O₅.

17. The display apparatus of claim 16, wherein the second passivation film has a thickness in a range of about 1 nm to about 15 nm.

18. The display apparatus of claim 13, wherein the first semiconductor layer includes a core rod, a plurality of nanopores open in an outward direction from the core rod, and quantum dots dispersed in the plurality of nanopores.

19. A method of manufacturing a semiconductor light-emitting device, the method comprising:
forming a first semiconductor layer on a substrate;
forming an active layer on the first semiconductor layer;
forming a second semiconductor layer on the active layer;
forming a plurality of light-emitting stack structures by etching the first semiconductor layer, the active layer, and the second semiconductor layer; and
depositing a first passivation film on the plurality of light-emitting stack structures,
wherein the plurality of light-emitting stack structures are configured to emit light having an emission peak wavelength in a range of about 400 nm to about 550 nm, and
wherein the first passivation film includes a tantalum oxide (TaxOy), and a composition ratio of the tantalum oxide of the first passivation film has a range of 0.1≤y/x≤10.

20. The method of claim 19, wherein a deposition temperature of the first passivation film is 250° C. or less.
